(19) United States
(12) Patent Application Publication
(10) Pub. No.: US 2025/0301785 A1
(43) Pub. Date: Sep. 25, 2025

(54) CROSS-COUPLE CONNECT IN STACKED FIELD EFFECT TRANSISTOR SEMICONDUCTORS

(71) Applicant: International Business Machines Corporation, Armonk, NY (US)

(72) Inventors: Albert M. Chu, Nashua, NH (US); Ruilong Xie, Niskayuna, NY (US); Brent A. Anderson, Jericho, VT (US); Lawrence A. Clevenger, Saratoga Springs, NY (US); David Wolpert, Poughkeepsie, NY (US); Nicholas Anthony Lanzillo, Wynantskill, NY (US)

(21) Appl. No.: 18/613,973

(22) Filed: Mar. 22, 2024

(51) Int. Cl. H01L 27/092; H01L 21/822; H01L 21/8238; H01L 27/06; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6219; H10D 30/6729; H10D 30/6735; H10D 30/6757; H10D 62/121; H10D 64/017; H10D 84/0167; H10D 84/0184; H10D 84/0193; H10D 84/038; H10D 84/853; H10D 88/00; H10D 88/01

(57) ABSTRACT

Embodiments are disclosed for a semiconductor structure. The semiconductor structure includes a stacked field effect transistor (SFET). The SFET includes a top FET disposed over a bottom FET. The semiconductor additionally includes a cross-couple connect (XCC). The XCC includes an angled gate contact that connects a bottom surface of a top gate of the top FET to a top surface of an adjacent bottom gate of an adjacent bottom FET of an adjacent contacted poly pitch (CPP).

### FIELD OF THE INVENTION

The present invention generally relates to semiconductor structures, and more particularly to bottom contact jumpers in stacked field effect transistor (SFET) semiconductor structures.

### BACKGROUND

Integrated circuit (IC) chips are formed on semiconductor wafers at increasingly smaller scale. In current technology nodes, such as 7, 10 and 14 nanometer technologies, transistor devices are constructed as three-dimensional (3D) fin FET (FINFET) structures. However, chipmakers face a myriad of challenges at 5 nm, 3 nm and beyond. Currently, traditional chip scaling continues to slow as process complexities and costs escalate at each node.

A potential solution to this chip scaling problem is gate all around technology. One example of a complex gate all around technology is a stacked FET where nFET and pFET nanowires/nanosheets are vertically stacked on top of each other.

### SUMMARY

Embodiments are disclosed for a semiconductor structure. The semiconductor structure includes a stacked field effect transistor (SFET). The SFET includes a top FET disposed over a bottom FET. The semiconductor additionally includes a cross-couple connect (XCC). The XCC includes an angled gate contact that connects a bottom surface of a top gate of the top FET to a top surface of an adjacent bottom gate of an adjacent bottom FET of an adjacent contacted poly pitch (CPP).

Embodiments are disclosed for a method of fabricating a semiconductor structure. The method includes forming a bottom device of the semiconductor structure. Additionally, the method includes bonding a top channel to the bottom device. Further, the method includes forming top channel patterning on the top channel. Also, the method includes forming an angled gate contact to the bottom device in a non-active region of the semiconductor structure. Additionally, the method includes removing a top high-k dielectric that is disposed over the angled gate contact. Further, the method includes forming a cross-couple by connecting a bottom surface of a top gate to the angled gate contact.

The present Summary is not intended to illustrate each aspect of, every implementation of, and/or every embodiment of the present disclosure. These and other features and advantages will become apparent from the following detailed description of the present embodiment(s), taken in conjunction with the accompanying drawings.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are illustrative of certain embodiments and do not limit the disclosure.

FIG. 1-1 is a top perspective view and cross-sectional views of example semiconductor structures during intermediate steps of a method for forming a cross-couple connect in stacked field effect transistor (SFET) semiconductors, in accordance with some embodiments of the present disclosure.

FIG. 1-2 is a top perspective view and cross-sectional views of example semiconductor structures during intermediate steps of a method for forming a cross-couple connect in SFET semiconductors, in accordance with some embodiments of the present disclosure.

FIG. 1-3 is a top perspective view and cross-sectional views of example semiconductor structures during intermediate steps of a method for forming a cross-couple connect in SFET semiconductors, in accordance with some embodiments of the present disclosure.

FIG. 1-4 is a top perspective view and cross-sectional views of example semiconductor structures during intermediate steps of a method for forming a cross-couple connect in SFET semiconductors, in accordance with some embodiments of the present disclosure.

FIG. 1-5 is a top perspective view and cross-sectional views of example semiconductor structures during intermediate steps of a method for forming a cross-couple connect in SFET semiconductors, in accordance with some embodiments of the present disclosure.

FIG. 1-6 is a top perspective view and cross-sectional views of example semiconductor structures during intermediate steps of a method for forming a cross-couple connect in SFET semiconductors, in accordance with some embodiments of the present disclosure.

FIG. 1-7 is a top perspective view and cross-sectional views of example semiconductor structures during intermediate steps of a method for forming a cross-couple connect in SFET semiconductors, in accordance with some embodiments of the present disclosure.

FIG. 1-8 is a top perspective view and cross-sectional views of example semiconductor structures during intermediate steps of a method for forming a cross-couple connect in SFET semiconductors, in accordance with some embodiments of the present disclosure.

FIG. 1-9 is a top perspective view and cross-sectional views of example semiconductor structures during intermediate steps of a method for forming a cross-couple connect in SFET semiconductors, in accordance with some embodiments of the present disclosure.

FIG. 1-10 is a top perspective view and cross-sectional views of example semiconductor structures during intermediate steps of a method for forming a cross-couple connect in SFET semiconductors, in accordance with some embodiments of the present disclosure.

FIG. 1-11 is a top perspective view and cross-sectional views of example semiconductor structures during intermediate steps of a method for forming a cross-couple connect in SFET semiconductors, in accordance with some embodiments of the present disclosure.

FIG. 2 is a process flow chart of a method for forming a cross-couple connect in SFET semiconductors, in accordance with some embodiments of the present disclosure.

While the present disclosure is amenable to various modifications and alternative forms, specifics thereof have been shown by way of example in the drawings and will be described in detail. It should be understood, however, that the intention is not to limit the present disclosure to the particular embodiments described. On the contrary, the intention is to cover all modifications, equivalents, and alternatives falling within the spirit and scope of the present disclosure.

### DETAILED DESCRIPTION

According to an aspect of the invention, there is provided a semiconductor structure. The semiconductor structure includes a stacked field effect transistor (SFET) having a top FET disposed over a bottom FET and a cross-couple connect (XCC). The XCC includes an angled gate contact that connects a bottom surface of a top gate of the top FET to a top surface of a bottom gate of an adjacent bottom FET of an adjacent contacted poly pitch (CPP). A technical advantage of the invention is to reduce the amount of area occupied by the combination of the top FET, XCC, and adjacent bottom FET.

In some embodiments, the angled gate contact is optionally disposed through a bonding dielectric between the top FET and the adjacent bottom FET. A technical advantage is to reduce the noise generated by the angled metal contact with respect to the FETs.

In some embodiments, a top S/D contact of the top FET is located over the angled gate contact. A technical advantage is to reduce the risk for short circuit between the top S/D contact and the XCC.

In some embodiments, the angled gate contact is in contact with a side surface of the adjacent bottom FET. A technical advantage is to increase the contact area between the angled gate contact and the adjacent bottom FET.

In some embodiments, a high-k gate dielectric is optionally located at sidewalls of the top gate of the top FET. A technical advantage is to reduce the area occupied by the semiconductor structure.

In some embodiments, the angled gate contact is optionally disposed over a non-active region of the semiconductor structure. A technical advantage is to prevent noise produced by the XCC from interfering with the top and bottom gates.

According to an aspect of the invention there is provided a semiconductor structure. The semiconductor structure includes an SFET. The SFET includes a top FET disposed over a bottom FET. Additionally, the semiconductor structure includes an XCC. The XCC includes an angled gate contact that connects a bottom surface of a top gate of the top FET to a top surface of a bottom gate of an adjacent bottom FET of an adjacent contacted poly pitch (CPP). Further, the angled gate contact is located over a non-active region of the semiconductor structure. A technical advantage of the invention is to reduce the amount of area occupied by the combination of the top FET, XCC, and adjacent bottom FET. Another technical advantage is to reduce the risk for short circuit between the top S/D contact and the XCC.

In some embodiments, the angled gate contact is optionally disposed through a bonding dielectric between the top FET and the adjacent bottom FET. A technical advantage is to reduce the area occupied by the semiconductor structure by using a direct path from the top FET to the adjacent bottom FET.

In some embodiments, a top S/D contact of the top FET is optionally located over the angled gate contact. A technical advantage is that the top S/D contact is at reduced risk for short circuit due in comparison to current solutions.

In some embodiments, the angled gate contact is in contact with a side surface of the adjacent bottom FET. A technical advantage is to increase the contact area between the angled gate contact and the adjacent bottom FET.

In some embodiments, a high-k gate dielectric is optionally located at sidewalls of the top gate of the top FET. A technical advantage is to reduce the area occupied by the semiconductor structure.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the example embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub lithographic” may refer to a dimension or size less than current dimensions achievable by photolithographic processes, and the term “lithographic” may refer to a dimension or size equal to or greater than current dimensions achievable by photolithographic processes. The sub lithographic and lithographic dimensions may be determined by a person of ordinary skill in the art at the time the application is filed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device having a dummy fin removed from within an array of tight pitch fins according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping, and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

In SFET semiconductors, neighboring SFETs form logic cells, and one useful type of logic cell is the scannable D-flip flop (SDFFQ.). The SDFFQ logic cell uses a cross-couple construct that connects the NFET gate to the PFET gate in the adjacent contacted poly-pitch (CPP). However, accommodating this construct (i.e., cross-couple connect) in an SFET design results in wider cell width and/or cell height. For example, it is possible to construct a cross-couple connect by realigning the NFET and PFET ordering, to share NFET and PFET gate connections. However, this realignment can increase the cell width by 1 CPP. Another approach involves accessing the bottom gate from the top metal. This approach may involve extending the bottom device (e.g., gate), narrowing the top gate, or some combination thereof. In this approach, the top and bottom gates are electrically isolated. Further, the PC extends beyond the active device to accommodate gate metallization and edge placement. Accordingly, this approach involves aggressive patterning, which can increase the risk of short circuit. In these ways, fabricating logic cells with cross-couple constructs can result in a costly area penalty, reducing the number of SFETs it is possible to fit within the limited space of a microprocessor.

Accordingly, some embodiments of the present disclosure provide an SFET semiconductor structure having cross-couple connections without increasing cell width and/or cell height. In such embodiments, an SFET device includes a cross-couple connect between a top gate and a bottom gate in an adjacent CPP. The latch cross-couple connect includes an angled gate contact through the bonding dielectric located between the top and bottom devices, over non-active regions. Further, the top source-drain (S/D) contact can fly over the latch cross-couple connect. In this way, such embodiments can provide a cross-couple connect in an SFET semiconductor structure that reduces the space used by current cross-couple connect devices. Accordingly, such devices can include SDFFQ and other logic cells in SFET semiconductor structures, with the same CPP as devices without cross-couple connects. In these ways, such embodiments can improve the operation of computer technology. However, some embodiments of the present disclosure may not achieve such advantages.

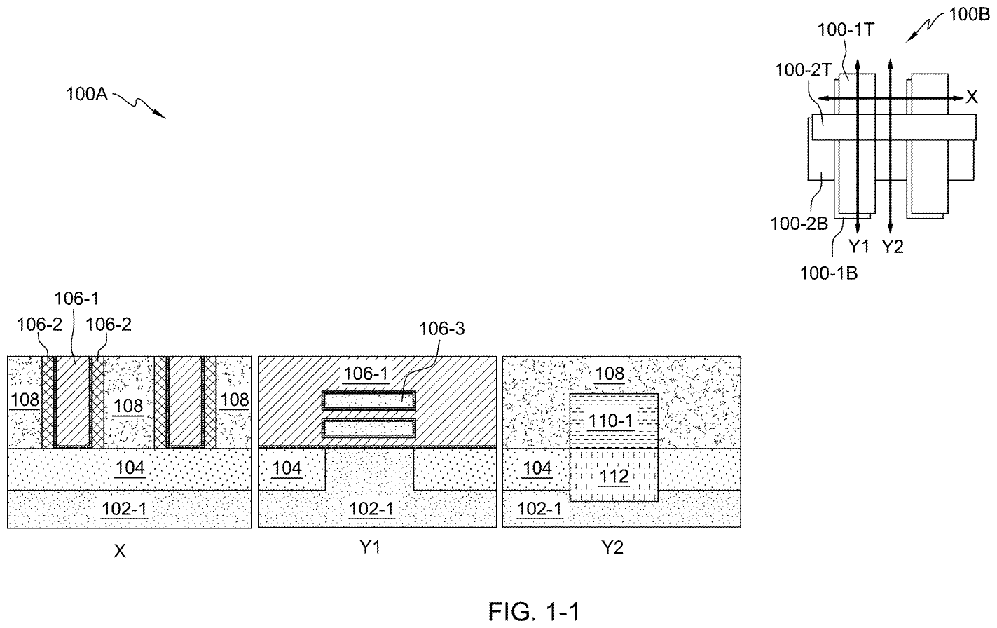

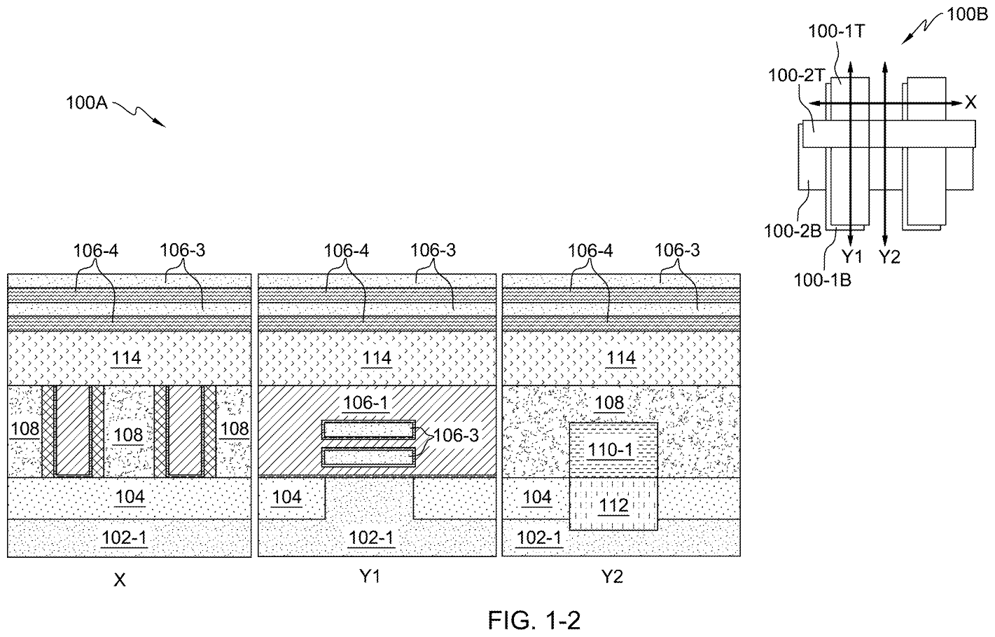

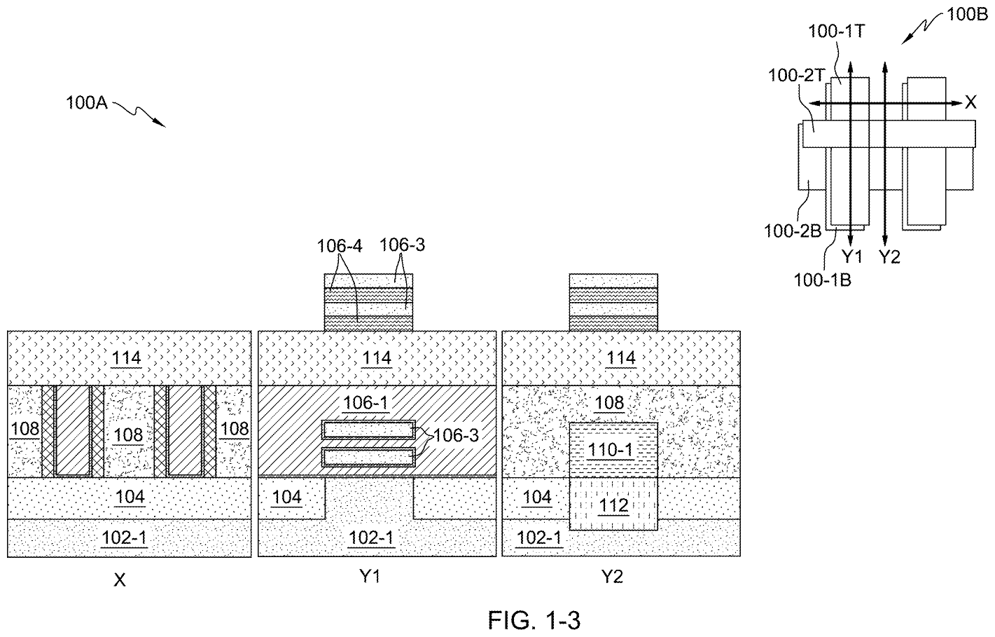

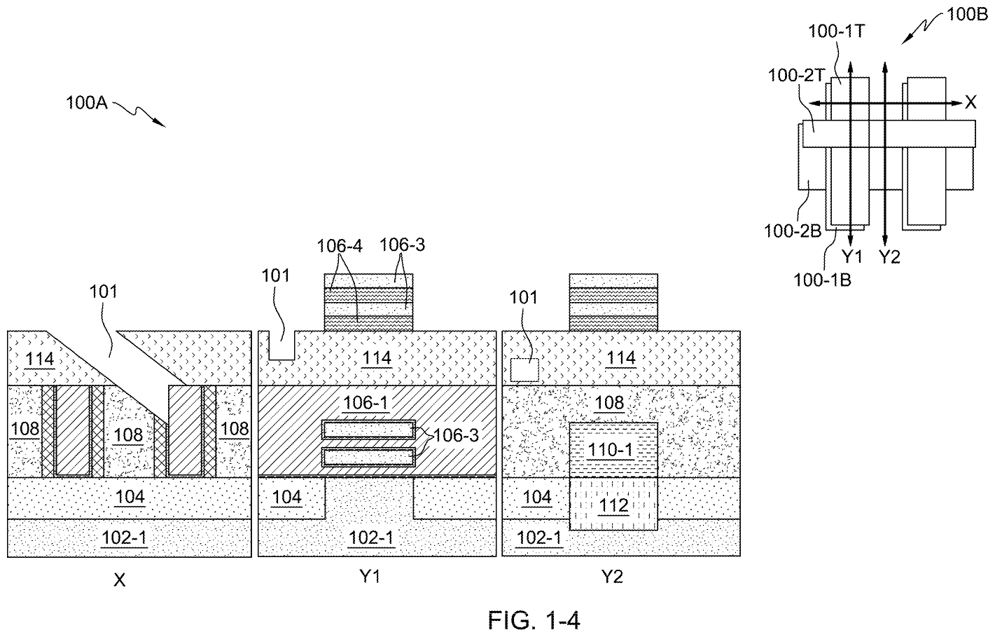

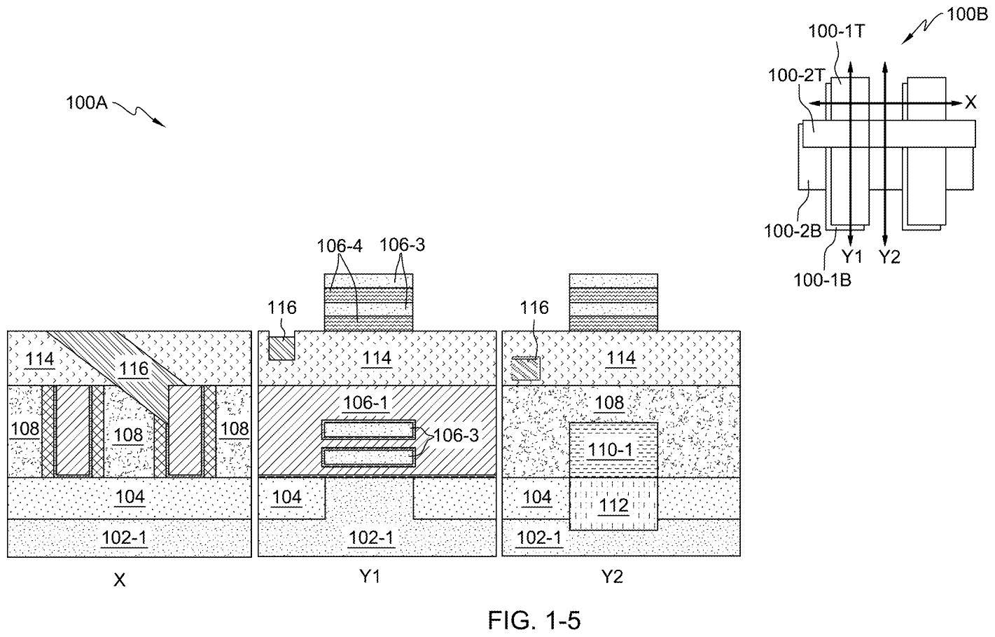

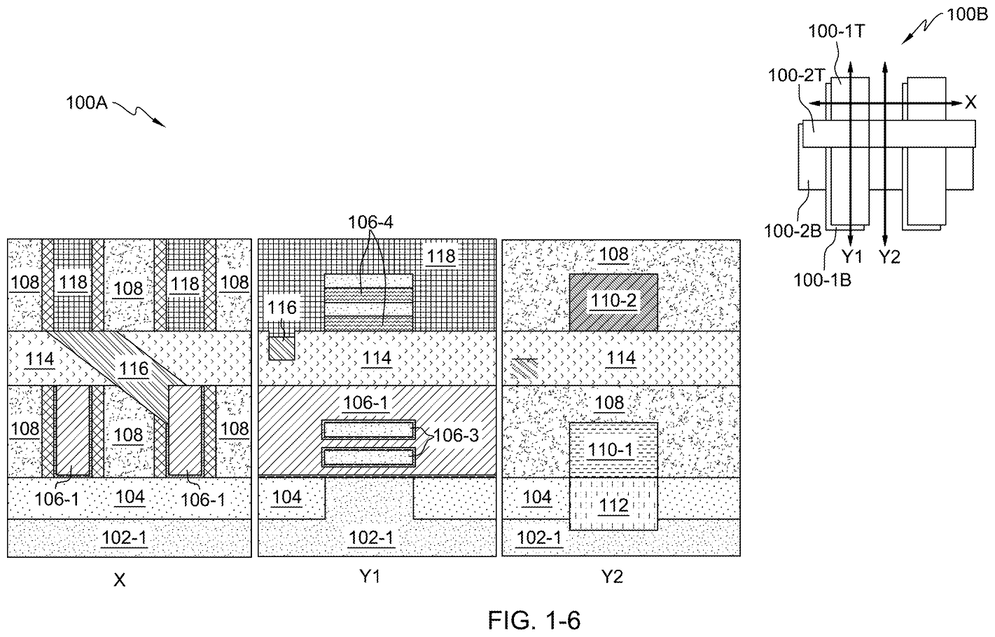

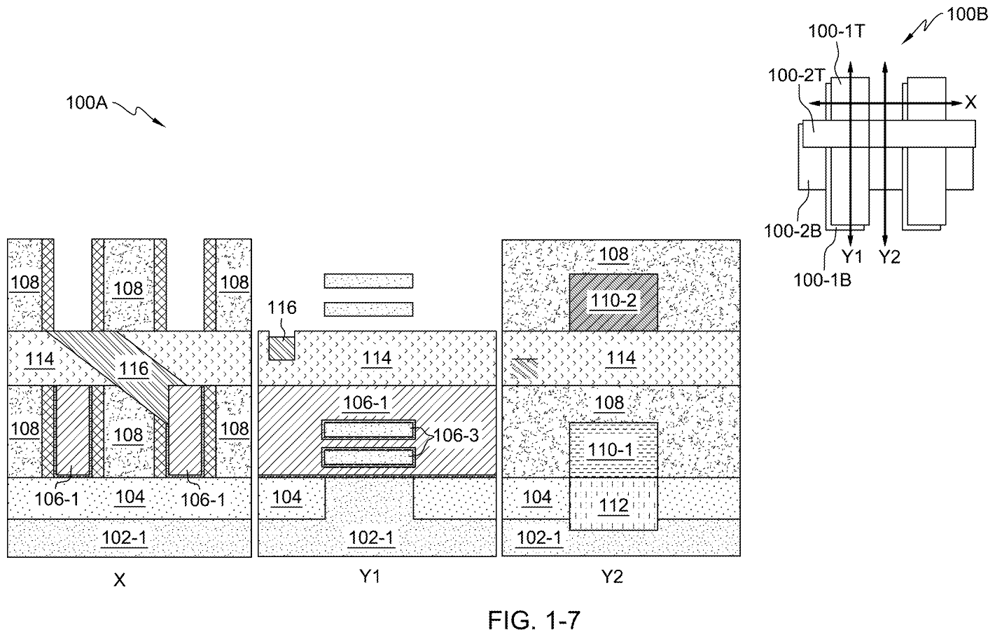

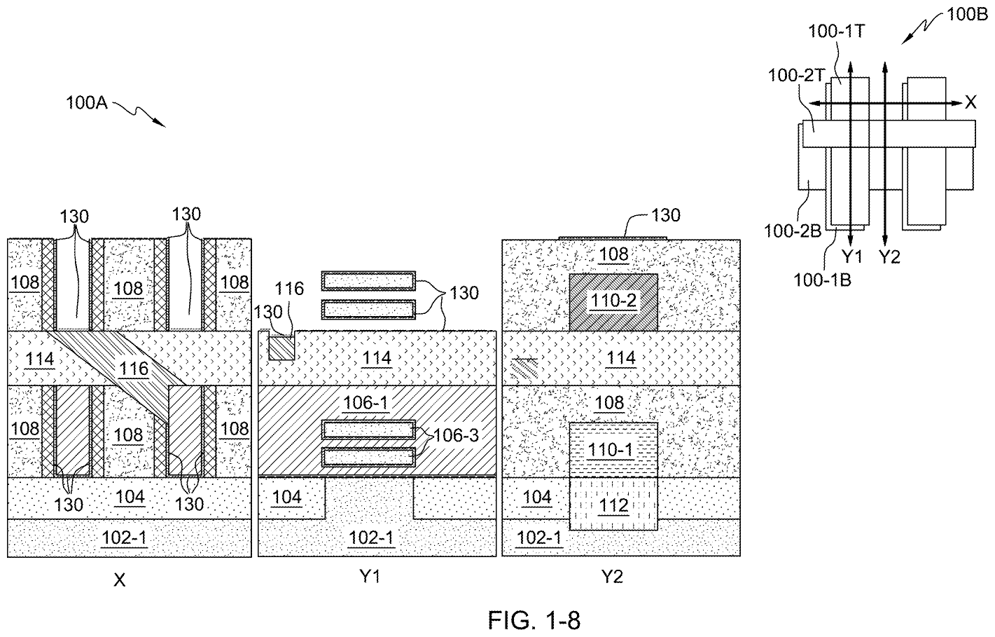

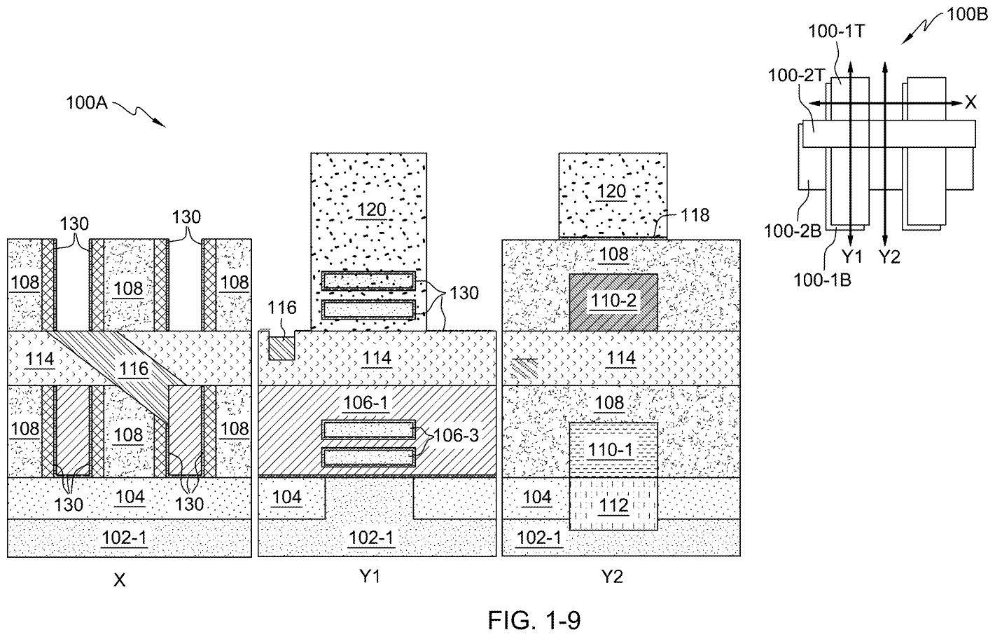

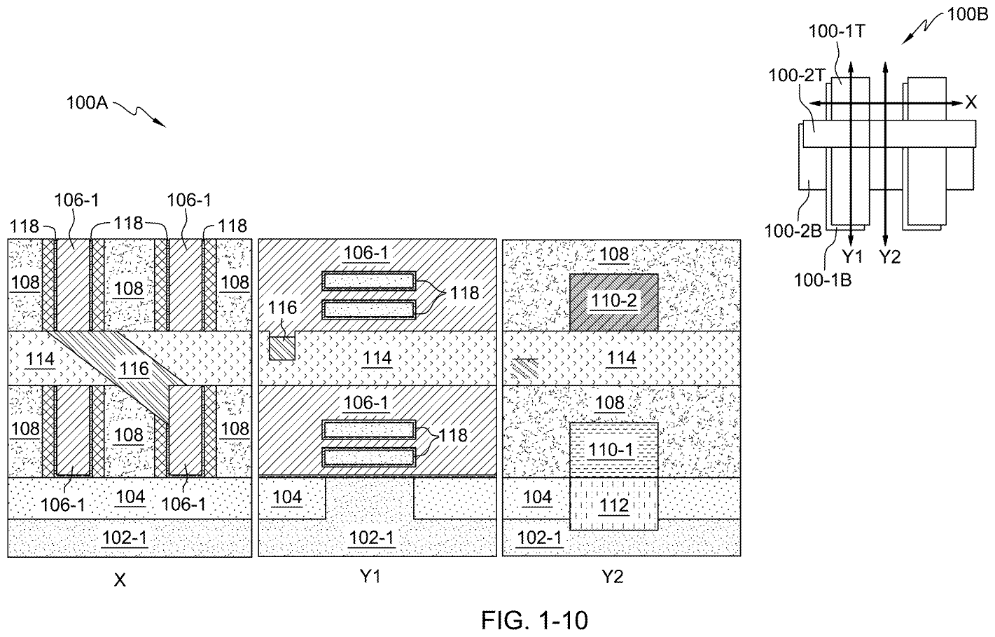

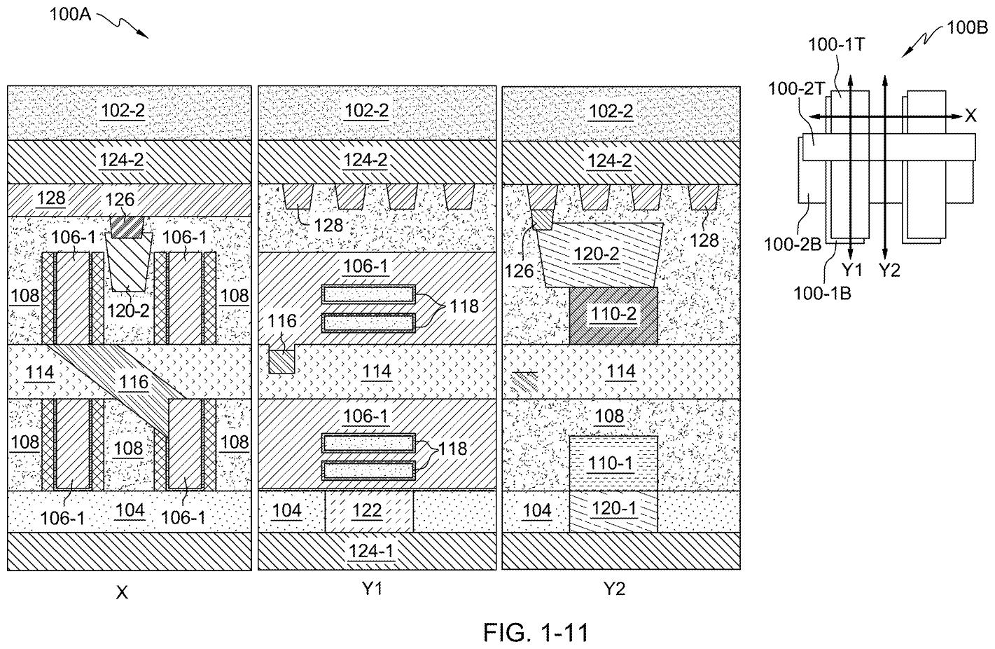

FIGS. 1-1 through 1-11 are top views and cross-sectional views of example semiconductor structures during intermediate steps of a method for forming a cross-couple connect in SFET semiconductors, in accordance with some embodiments of the present disclosure. For clarity, not all elements are labelled in these figures. Rather, representative elements are labelled, with similar elements being indicated by position, size, shape, hash lines (or lack thereof), and the like, in subsequent figures.

FIG. 1-1 is a top perspective view of example semiconductor structure 100A and cross-sectional views of example semiconductor structure 100B during intermediate steps of a method for forming a cross-couple connect in SFET semiconductors, in accordance with some embodiments of the present disclosure. The example semiconductor structure 100A includes top gate layers 100-1T, bottom gate layers 100-1B (collectively referred to as gate layers 100-1), top device layer 100-2T and bottom device layer 100-2B (collectively referred to as device layers 100-2). Additionally, the top perspective view includes cut lines X, Y1, and Y2. The cut lines X, Y1, and Y2 correlate to the cross-sectional views X, Y1, and Y2, of the semiconductor structure 100B. As shown, the cross-sectional view X includes the gate layers 100-1. Additionally, the cross-sectional view Y1 includes one of the top gate layers 100-1T, one of the bottom gate layers 100-1B, and the device layers 100-2. Further, the cross-sectional view Y2 includes the device layers 100-2. In FIG. 1-1, there are no top layers shown in the cross-sectional views. However, the top layers are shown in the cross-sectional views of the subsequent figures.

The example semiconductor structure 100B may result from a fabrication method wherein materials constituting each of the elements is deposited, applied, and otherwise arranged as shown. More specifically, the example semiconductor structures 100A, 100B may result from bottom device formation. The processes and formation of structures during bottom device formation is not within the scope of this disclosure and may be performed using known methods and techniques.

As shown in view X, the example semiconductor structure 100B includes a substrate 102-1, shallow trench isolation (STI) layer 104, high-k gate material (HKMG) 106-1, spacers 106-2, and interlayer dielectric (ILD) 108. The substrate 102-1 can be a semiconductor or an insulator with an active surface semiconductor layer. The substrate 102-1 can be crystalline, semi-crystalline, microcrystalline, or amorphous. The substrate 102-1 can be (except for contaminants) a single element (e.g., Si), primarily (e.g., with doping) of a single element, for example, Si or Ge, or the substrate 102-1 can include a compound, for example, aluminum oxide (Al2O3), silicon dioxide (SiO2), gallium arsenide (GaAs), silicon carbide (SiC), or SiGe. The substrate 102-1 can also have multiple material layers, for example, a semiconductor-on-insulator substrate (SeOI), a silicon-on-insulator substrate (SOI), germanium-on-insulator substrate (GeOI), or silicon-germanium-on-insulator substrate (SGOI). The substrate 102-1 can also have other layers forming the substrate 102, including high-k oxides and/or nitrides. In one or more embodiments, the substrate 102-1 can be a silicon wafer. In an embodiment, the substrate 102 can be a single crystal silicon wafer. The STI layer 104 may isolate the bottom device from back end of line (not shown) in the constructed semiconductor structure. The spacers 106-2 can represent a dielectric material that provides a spacing between the HKMG 106-1 and the ILD 108.

As shown in view Y1, the example semiconductor structure 100B includes the substrate 102-1, STI layer 104, HKMG 106-1, and channel layers 106-3. The channel layers 106-3 can include nanosheets of semiconductor material, which can be conductive in a transistor, “on” state, or highly resistive in a transistor, “off” state. The conductivity can be controlled by the HKMG 106-1. Additionally, in view Y2, the example semiconductor structure 100B includes the substrate 102-1, STI layer 104, ILD 108, top S/D epitaxial 110-1 of the bottom device, and a placeholder 112. The placeholder 112 may be comprised of a dielectric material.

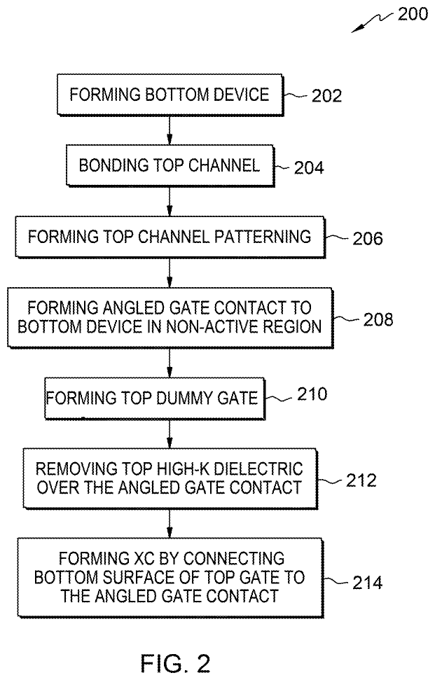

FIG. 1-2 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from bonding a top channel to the bottom device, e.g., the semiconductor structure 100B, described with respect to FIG. 1-1. Bonding the top channel involves depositing a bonding oxide layer 114 on the semiconductor structure 100B, for example. Additionally, bonding the top channel involves depositing nanosheets of alternating sacrificial layers 106-4 and channel layers 106-3 on the bonding oxide layer 114. As shown, in addition to the bottom device, the cross-sectional views X, Y1, and Y2 include the bonding oxide layer 114, channel layers 106-3, and sacrificial layers 106-4.

FIG. 1-3 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from forming top channel patterning on the semiconductor structure 100B, described with respect to FIG. 1-2. Forming channel patterning involves removing portions of the channel layers 106-3 and sacrificial layers 106-4 from the top gate layers 100-1T and device layer 100-2T. In the cross-sectional view X, all of the material of the channel layers 106-3, and sacrificial layers 106-4 is removed in the top gate layer 100-1T. In contrast, the views Y1, Y2 include the remaining portions (e.g., pattern) of the channel layers 106-3 and sacrificial layers 106-4 after forming the top channel patterning.

FIG. 1-4 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from performing angled reactive ion etching (RIE) for a cross-couple gate contact. Performing the RIE in this way can involve generating the trench 101 by removing portions of the bonding oxide layer 114 and ILD 108 in an inactive region. This exposes the top and side regions of the bottom gate contact, i.e., HKMG 106-1. Additionally, the top of the trench 101 is located near a bottom region of the top gate contact in the CPP that is adjacent to the CPP having the exposed HKMG 106-1. The trench 101 is included in the cross-sectional views X and Y1.

FIG. 1-5 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from angled gate contact metallization and recess on the semiconductor structures 100A, 100B, described with respect to FIG. 1-4. More specifically, performing angled gate contact metallization can involve depositing metal in the trench 101, thus generating the cross-couple connect 116, included in views X and Y1.

FIG. 1-6 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from forming the top dummy gate, spacers, inner spacers (not shown), S/D epitaxials; performing an ILD deposit; and, performing chemical-mechanical planarization (CMP) on the semiconductor structures 100A, 100B, described with respect to FIG. 1-5. Forming the top dummy gate can involve depositing dummy gate material 118 (included in views X and Y1). Forming the spacers 119 (included in view X) can involve depositing a dielectric material along the sides of the dummy gate material 118. Forming the top S/D epitaxials 110-2 (included in view Y2) can involve performing an epitaxial growth on the portion of the bonding oxide layer 114 in the device layer 100-2. Performing the ILD deposit forms the ILD layer 108 included in views X and Y2. Performing the CMP can involve removing material from the top of the semiconductor structures 100A, 100B, to leave a planarized surface on the ILD layer 108, dummy gate material 118, and spacers 119, as shown in views X, Y1, and Y2.

FIG. 1-7 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from performing dummy gate removal and sacrificial layer removal on the semiconductor structures 100A, 100B, described with respect to FIG. 1-6. Removing the dummy gate and sacrificial layer can involve an etching process selective to the dummy gate material 118 and sacrificial layers 106-4, respectively. Accordingly, the views X, Y1, and Y2 show open space in the regions previously occupied by the dummy gate material 118 and sacrificial layers 106-4.

FIG. 1-8 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from depositing a high-k dielectric material on the semiconductor structures 100A, 100B, described with respect to FIG. 1-7. More specifically, depositing the high-k dielectric material in this way forms a high-k liner 130 on the semiconductor structures 100A, 100B. For example, view X includes the high-k liner 130 deposited along the sides of the spacers 119 in the top and devices. Further, in the bottom device of view X, the high-k layer is additionally deposited on the STI layer 104 in the region between and beneath the spacers 119. The high-k liner 130 isolates the gates (with the top gate still to be formed) from each other and each of the front end and back end interconnects.

FIG. 1-9 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from high-k open patterning on the semiconductor structures 100A, 100B, described with respect to FIG. 1-8. Performing high-k open patterning involves depositing a material forming an organic planarization layer (OPL) 120 on the semiconductor structures 100A, 100B. Additionally, high-k open patterning can involve removing portions of the OPL 120 to expose portions of the underlying structure. More specifically view X includes none of the remaining OPL 120. Additionally, views X, Y1, and Y2 show that where the OPL 120 is removed, the underlying high-k liner 130 is also removed. Thus, high-k open patterning exposes the cross-couple connect 116 (shown in views X and Y1).

FIG. 1-10 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from work function metal deposit, tungsten deposit, and CMP on the semiconductor structures 100A, 100B, described with respect to FIG. 1-9. Performing work function metal deposit can involve depositing a work function metal, such as a metal gate (e.g., HKMG 106-1) in the gate openings. Additionally, the tungsten deposit can involve depositing a tungsten layer on the semiconductor structures 100A, 100B. Further, the CMP may involve removing the tungsten layer and forming a planarization on the top of the semiconductor structures 100A, 100B.

FIG. 1-11 is a top perspective view and cross-sectional views of example semiconductor structures 100A, 100B, respectively, during intermediate steps of a method for forming a cross-couple connect in SFET semiconductors, in accordance with some embodiments of the present disclosure. The semiconductor structures 100A, 100B can result from forming frontside and backside interconnects on the semiconductor structures 100A, 100B, described with respect to FIG. 1-9. Forming the frontside interconnect can involve flipping the semiconductor structure 100B, removing the substrate 102-1, forming top S/D contacts 120-1, vias 126, metal lines 128, a front end of line (FEOL) interconnect 124-1, and a substrate 102-2. Forming the backside interconnect can involve forming the gate contacts 122 and back end of line (BEOL) interconnect 124-2. While elements of the frontside and backside interconnects are represented in views X, Y1, and Y2, forming frontside and backside interconnects is beyond the scope of this disclosure, and not further described.

FIG. 2 is a process flow chart of a method 400 for forming a cross-couple connect in SFET semiconductors, in accordance with some embodiments of the present disclosure. The method 400 may be similar to the method represented in FIGS. 1-1 through 1-11, to produce a semiconductor structure.

At operation 402, a fabrication tool can form a bottom device semiconductor structure. Forming the bottom device semiconductor structure is described with respect to FIG. 1-1.

At operation 404, a fabrication tool may bond the top channel to the semiconductor structure, described with respect to FIG. 1-2. Bonding the top channel can involve depositing the bonding oxide layer 114 on the semiconductor structure 100B, and depositing nanosheets of alternating channel layers 106-3 and sacrificial layers 106-4 on the bonding oxide layer 114.

At operation 406, a fabrication tool can form top channel patterning, described with respect to FIG. 1-3. As stated previously, performing top channel patterning involves removing portions of the channel layers 106-3 and sacrificial layers 106-4 from the top gate layers 100-1T and top device layer 100-2T.

At operation 408, a fabrication tool can form an angled gate contact to the bottom device in a non-active region of the semiconductor structure, described with respect to FIGS. 1-4 through 1-5. Forming the angled gate contact to the bottom device involves performing an angled RIE for the cross-couple contact and performing angled gate contact metallization and recess in the trench created by the angled RIE.

At operation 410, a fabrication tool can form a top dummy gate, described with respect to FIG. 1-6. As stated previously, forming the top dummy gate involves depositing ILD 108, dummy gate material 118, and spacers 119 on the semiconductor structure.

At operation 412, a fabrication tool can remove the top high-k dielectric over the angled gate contact, described with respect to FIG. 1-9. Removing the top high-k dielectric involves removing the high-k liner 130 from the semiconductor structure.

At operation 414, a fabrication tool can form the cross-couple by connecting the bottom surface of the top gate to the angled gate contact, described with respect to FIG. 1-10. Forming the cross-couple involves depositing the work function metal of the HKMG 106-1 to form the top gates.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks. When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category. For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations. Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A semiconductor structure comprising:
a stacked field effect transistor (SFET) comprising a top FET disposed over a bottom FET; and
a cross-couple connect (XCC), comprising an angled gate contact that connects a bottom surface of a top gate of the top FET to a top surface of a bottom gate of an adjacent bottom FET of an adjacent contacted poly pitch (CPP).

2. The semiconductor structure of claim 1, wherein the angled gate contact is disposed through a bonding dielectric between the top FET and the adjacent bottom FET.

3. The semiconductor structure of claim 1, wherein a top S/D contact of the top FET is disposed over the angled gate contact.

4. The semiconductor structure of claim 1, wherein the angled gate contact is in contact a side surface of the adjacent bottom FET.

5. The semiconductor structure of claim 4, wherein there is no high-k gate dielectric disposed at sidewalls of a bottom gate of the adjacent bottom FET.

6. The semiconductor structure of claim 1, wherein the angled gate contact is disposed over a non-active region of the semiconductor structure.

7. The semiconductor structure of claim 1, wherein the semiconductor structure further includes the adjacent CPP.

8. A semiconductor structure comprising:
a stacked field effect transistor (SFET) comprising a top FET disposed over a bottom FET; and
a cross-couple connect (XCC), comprising an angled gate contact that connects a bottom surface of a top gate of the top FET to a top surface of a bottom gate of an adjacent bottom FET of an adjacent contacted poly pitch (CPP), wherein the angled gate contact is disposed over a non-active region of the semiconductor structure.

9. The semiconductor structure of claim 8, wherein the angled gate contact is disposed through a bonding dielectric between the top FET and the adjacent bottom FET.

10. The semiconductor structure of claim 8, wherein a top S/D contact of the top FET is disposed over the angled gate contact.

11. The semiconductor structure of claim 8, wherein the angled gate contact is in contact a side surface of the adjacent bottom FET.

12. The semiconductor structure of claim 8, wherein a high-k gate dielectric is disposed at sidewalls of the top gate of the top FET.

13. The semiconductor structure of claim 8, wherein the semiconductor structure further includes the adjacent CPP.

14. A method for fabricating a semiconductor structure, the method comprising:
forming a bottom device of the semiconductor structure comprising an adjacent bottom FET and an adjacent bottom gate;
bonding a top channel to the bottom device;
forming top channel patterning on the top channel;
forming an angled gate contact to the bottom device in a non-active region of the semiconductor structure;
removing a top high-k dielectric that is disposed over the angled gate contact;
forming a top gate on the top channel; and
forming a cross-couple connect by connecting a top FET to the angled gate contact.

15. The method of claim 14, further comprising forming the high-k dielectric along a plurality of sides of the top gate.

16. The method of claim 14, wherein forming the top gate comprises forming a dummy gate, removing the dummy gate, and form a high-k metal gate.

17. The method of claim 16, further comprising forming spacers along a plurality of sides of the top gate.

18. The method of claim 16, further comprising forming an angled trench for the angled gate contact through a bonding dielectric disposed between the top gate and the adjacent bottom gate.
